(19) United States
(12) Patent Application Publication
(10) Pub. No.: US 2008/0036022 A1
(43) Pub. Date: Feb. 14, 2008

(54) Image sensor and method of manufacturing the same

(76) Inventors: Sung-ho Hwang, Yongin-si (KR); Duck-hyung Lee, Yongin-si (KR); Chang-rok Moon, Seocho-gu (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/785,196

(22) Filed: Apr. 16, 2007

(30) Foreign Application Priority Data
Aug. 11, 2006 (KR) 10-2006-0076346

(51) Int. Cl. H01L 31/052; H01L 31/18

(52) U.S. Cl. 257/432; 438/70; 257/E31.127; 257/E21.52

(57) ABSTRACT

An image sensor and a method of manufacturing same is disclosed. The image sensor implements a reflecting film formed on a front surface of a substrate having a back-illuminated photodetector. The reflecting film operates to reflect wavelengths of light that were not received by the photodetector back to the photodetector to increase the overall sensitivity of the image detector. The reflective film is formed by layering different thicknesses of material with different indices of refraction, resulting in a high reflectance.

### BACKGROUND OF THE INVENTION

1. Field of the Invention

The present invention relates to an image sensor and a method of manufacturing same. More particularly, the invention relates to an image sensor having a reflecting film capable of reflecting light in a red wavelength range to improve the sensitivity of a photoelectric converter and a method of manufacturing the image sensor.

This application claims priority from Korean Patent Application No. 10-2006-0076346, filed on Aug. 11, 2006, the subject matter of which is hereby incorporated by reference in its entirety.

2. Description of the Related Art

Image sensors are semiconductor devices for converting incident light into electric signals. Image sensors are generally divided into two main types, that is, charge coupled devices (CCDs) or CMOS image sensors.

Charge coupled devices have MOS capacitors closely adjacent to each other, where the MOS capacitors operate to store and transfer charges. Conversely, CMOS image sensors have a plurality of unit pixels for converting charge into a voltage, and then output signals from signal lines by a switching operation.

For the CMOS image sensor, due to the increase in the integration of semiconductor devices, it is necessary to correspondingly reduce the size of a pixel.

The CMOS image sensor includes an active pixel sensor area in which a plurality of unit pixels are arranged in a matrix and a peripheral circuit area in which peripheral circuits for controlling the unit pixels or processing signals of the unit pixels are formed. In particular, the active pixel sensor area is divided into a photoelectric converter for converting light energy into electric signals and a logic element for processing the converted electric signals to generate data.

In the related art of CMOS image sensors, light is transferred from a lens, which is formed on a plurality of wiring layers, to a photoelectric converter through the wiring layers, whereby the light incident on the photoelectric converter is detected. In the related art, however, an insufficient amount of the incident light actually reaches the photoelectric converter due to the interference of the multi-layer wiring line. That is, the layout of the multi-layer wiring line reduces the aperture ratio of the photoelectric converter, which causes light incident on the photoelectric converter to be markedly reduced, resulting in low sensitivity.

In order to solve the above-mentioned problem, a back-illuminated image sensor has been proposed. In the back-illuminated image sensor, light is illuminated from the back side (the side opposite to the wiring portion) of the semiconductor substrate, and the photoelectric converter receives the light. In this way, it is possible to improve the effective aperture ratio without degradation from the layout of a plurality of wiring layers, and thereby considerably raise sensitivity. However, when light is illuminated from the back side of the semiconductor substrate, all light components in the red wavelength range, which is a long wavelength range of visible light, may not be incident on the photoelectric converter. Rather, some of the light components may pass through the photoelectric converter in the semiconductor substrate and through the interlayer insulating film on the semiconductor substrate. As a result, some of the light components in the red wavelength range that should contribute to an improvement in the sensitivity of the photoelectric converter are lost, which causes the red sensitivity to be lowered.

Therefore, there is a need for a semiconductor device and method capable of substantially overcoming the deficiencies described above.

### SUMMARY OF THE INVENTION

The present invention provides various systems and methods for increasing the amount of detected light (more noticeably long wavelength radiation) in a back-illuminated image sensor, by incorporating a reflecting/refracting film for that is disposed in the semiconductor device.

According to one aspect of the present invention, there is provided an image sensor that includes, a semiconductor substrate, photoelectric converters formed in the substrate, microlenses formed on a surface of the substrate at positions corresponding to the photoelectric converters, and a reflecting film formed on an opposite surface of the substrate, the reflecting film having at least one or more laminated refractive films, wherein each one of the laminated refractive films has a first refractive film and a second refractive film.

According to another aspect of the present invention, there is provided a method of manufacturing an image sensor, the method including forming photoelectric converters in a semiconductor substrate, forming a reflecting film on one surface of the substrate, the reflecting film having at least one or more laminated refractive films, each of the laminated refractive films having a first refractive film and a second refractive film, polishing the opposite surface of the substrate, and forming microlenses on the polished surface of the substrate at positions corresponding to the photoelectric converters.

Details of other embodiments of the invention are included in the detailed description of the invention and the drawings.

### BRIEF DESCRIPTION OF THE DRAWINGS

The above and other features and advantages of the present invention will become more apparent by describing in detail preferred embodiments thereof with reference to the attached drawings in which:

FIG. 1 is a block diagram illustrating an image sensor according to an exemplary embodiment of the invention;

FIG. 2 is a circuit diagram illustrating an image sensor according to an exemplary embodiment of the invention;

FIG. 3 is a cross-sectional view of an image sensor according to an exemplary embodiment of the invention;

FIG. 4 is a cross-sectional view of an image sensor according to another exemplary embodiment of the invention;

FIG. 5 is a cross-sectional view of an image sensor according to another exemplary embodiment of the invention;

FIG. 6 is a layout view of an image sensor according to another exemplary embodiment of the invention;

FIGS. 7A to 7C are cross-sectional views illustrating exemplary methods of manufacturing an image sensor according to exemplary embodiments of the invention;

FIG. 8 is a graph illustrating the relationship between the depth of a silicon substrate and the transmittance of light in a long wavelength range in an image sensor not having a reflecting film; and

FIG. 9 is a graph illustrating the relationship between wavelength and the transmittance of light in an image sensor provided with a reflecting film in accordance with an exemplary embodiment of the invention.

### DESCRIPTION OF THE EMBODIMENTS

Embodiments of the invention will be described in some additional detail with reference to the accompanying drawings. The present invention may, however, be embodied in different forms and should not be constructed as limited to only the embodiments set forth herein. Rather, these embodiments are presented as teaching examples. Throughout the written description and drawings, like reference numbers and symbols refer to like or similar elements.

Certain drawing dimensions, particularly those related to elements, layers and regions of the exemplary interconnects described below may have been exaggerated for clarity. It will also be understood that when a layer is referred to as being ‘on’ another layer, element, or region, it may be “directly on” the other layer, element, or region, or intervening layers may also be present. Further, it will be understood that when a layer is referred to as being ‘under’ another layer, it may be “directly under”, or one or more intervening layers may be present. In addition, it will also be understood that when a layer is referred to as being ‘between’ two layers, elements, or regions, it may be the only layer there between, or one or more intervening layers may also be present.

Moreover, terms such as “first,” and “second” are used to describe various layers, elements, and regions in various embodiments of the invention, but such terms do not temporally or sequentially limit (e.g., in an order of formation) the related layers, elements, and regions. Rather, these terms are used merely to distinguish one layer, element or region from another.

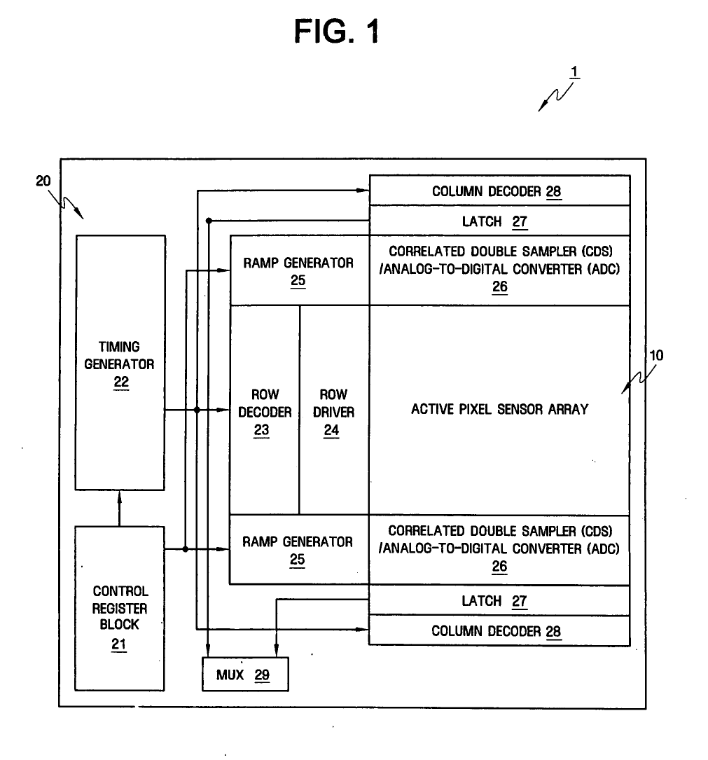

FIG. 1 is a block diagram illustrating an image sensor 1 according to an exemplary embodiment of the present invention. The exemplary image sensor 1 includes two main areas—an active pixel sensor area 10 and a peripheral circuit area 20.

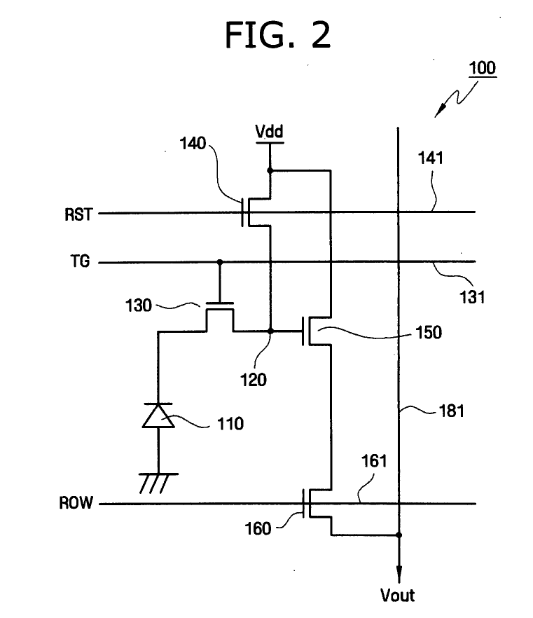

The active pixel sensor area 10 includes a plurality of unit pixels arranged in a matrix. The plurality of unit pixels absorbs the energy of light reflected from an object and converts the energy into electrical signals. The active pixel sensor area 10 operates in response to a plurality of driving signals, such as, for example, a pixel selection signal ROW, a reset signal RST, and a charge transmission signal TG, received from a row driver 24. The active pixel sensor area 10 provides the converted electrical signal to a correlated double sampler/analog-to-digital converter 26 via a vertical signal line. The unit pixel will be described in detail below with reference to FIG. 2.

The peripheral circuit area 20 controls the unit pixels in the active pixel sensor area 10 or processes signals of the unit pixels. The peripheral circuit area 20 includes controlling devices, for example, a control register block 21, a timing generator 22, a row decoder 23, the row driver 24, a ramp generator 25, the correlated double sampler/analog-to-digital converter 26, a latch 27, a column decoder 28, and a multiplexer (MUX) 29.

The timing generator 22 operates to provide a timing signal and a control signal to the row decoder 23 and to the column decoder 28.

The row driver 24 operates to provide a plurality of driving signals to the active pixel sensor area 10 to drive the plurality of unit pixels according to the decoding result of the row decoder 23. In general, when the unit pixels are arranged in a matrix, the driving signal is provided to each row of unit pixels.

The correlated double sampler/analog-to-digital converter 26 receives the electric signal formed in the active pixel sensor area 10 via the vertical signal line and performs holding and sampling operations. That is, the correlated double sampler/analog-to-digital converter 26 double samples a predetermined reference voltage level (hereinafter, referred to as a “noise level”) and a voltage level of the electric signal (hereinafter, referred to as a “signal level”) and outputs a differential level corresponding to the difference between the noise level and the signal level. The correlated double sampler/analog-to-digital converter 26 operates to convert an analog signal corresponding to the differential level into a digital signal and then outputs the digital signal.

The latch 27 latches the digital signal. The latched signal is supplied to the MUX 29. The MUX 29 arranges all the supplied signals in series, and provides the signals arranged in series to a resident or non-resident image signal processor (not shown).

FIG. 2 is a circuit diagram of an exemplary image sensor 100 according to an embodiment of the invention. The unit pixel 100 of the image sensor 1 includes a photoelectric converter 110, a charge detector 120, a charge transmitter 130, a reset unit 140, an amplifier 150, and a selector 160.

The photoelectric converter 110 absorbs the energy of light reflected from an object and stores the charge corresponding to the energy of the reflected light. The photoelectric converter 110 may be a photodiode, a phototransistor, a photogate, a pinned photodiode (PPD), a combination thereof, or any now known or future-devised photosensitive device.

The charge detector 120 is implemented as a floating diffusion (FD) region and receives the charge stored in the photoelectric converter 110. Since the charge detector 120 has parasitic capacitance, the electric charge is cumulatively stored in the charge detector 120. The charge detector 120 is electrically connected to the gate of the amplifier 150 and thus controls the amplifier 150.

The charge transmitter 130 transmits the charge from the photoelectric converter 110 to the charge detector 120. In general, the charge transmitter 130 includes a transistor and is controlled by charge transmission signal TG.

The reset unit 140 periodically resets the charge detector 120. The source of the reset unit 140 is connected to the charge detector 120, and the drain thereof is connected to a power supply voltage terminal Vdd. The reset unit 140 operates in response to the reset signal RST.

The amplifier 150 in combination with a constant current source (not shown) positioned outside the unit pixel 100 functions as a source follower buffer amplifier. A voltage varying in response to the voltage of the charge detector 120 is output from the amplifier 150 to a vertical signal line 181. The source of the amplifier 150 is connected to the drain of the selector 160 and the drain thereof is connected to the power supply voltage terminal Vdd.

The selector 160 selects each row of unit pixels 100 to be read. The selector 160 operates in response to the pixel selection signal ROW, and the source of the selector 160 is connected to the vertical signal line 181.

In addition, driving signal lines 131, 141, and 161 of the charge transmitter 130, the reset unit 140, and the selector 160, respectively, extend in a row direction (horizontal direction) such that the unit pixels belonging to the same row are simultaneously driven.

FIG. 3 is a cross-sectional view of an exemplary image sensor 30 according to an embodiment of the invention. The image sensor 30 is a back-illuminated image sensor in which a microlens 320 is formed on a rear surface of the semiconductor substrate 102.

In the exemplary image sensor 30, a plurality of unit pixels are arranged in a matrix on the semiconductor substrate 102. Each unit pixel includes a device isolation region 106, the photoelectric converter 110, the charge detector 120, the charge transmitter 130, the reset unit 140, a reflecting film 190, and an interlayer insulating film 200. For the purposes of illustration, a pinned photodiode (PPD) is used as an example of the photoelectric converter 110.

A P-type substrate may mainly be used as the semiconductor substrate 102. Although not shown in the drawings, the photoelectric converter 110, the charge transmitter 130, and the reset unit 140 may be formed, for example, on a P-type epitaxial layer and/or a well region by growing the P-type epitaxial layer on the semiconductor substrate 102 or providing a separate well region thereon.

The device isolation region 106 defines an active region on the semiconductor substrate 102. In general, the device isolation region 106 may be, for example, a field oxide (FOX) or shallow trench isolation (STI) region formed using a LOCOS (local oxidation of silicon) method.

The photoelectric converter 110 absorbs light energy to generate charge and stores the charge. The photoelectric converter 110 includes an N+-type photodiode 112 and a P+-type pinning layer 114. In general, the photodiode 112 and the pinning layer 114 can be formed by two different ion implantation processes.

It is understood that for image sensors in the related art, surface damage of the photodiode 112 results in a dark current. The surface damage may be caused by dangling silicon bonds, or it may be caused by other defects, such as, related to etching stress during the manufacture of, for example, a gate or a spacer. When the photodiode 112 is formed deep in the semiconductor substrate 102 and then the pinning layer 114 is formed, it is possible to prevent the dark current and to easily transmit charge generated by light energy.

The charge detector 120 receives the charge stored in the photoelectric converter 110 via the charge transmitter 130. The charge detector 120 is formed by implanting ions of an N+ dopant.

The charge transmitter 130 is formed of a transistor, which is a switching element, and includes a first gate insulating film 132, a first gate electrode 134, and a first spacer 136.

The reset unit 140 is also formed of a transistor, which is a switching element, and includes a second gate insulating film 142, a second gate electrode 144, and a second spacer 146.

The reflecting film 190 is formed on the semiconductor substrate 102, that is, on the photoelectric converter 110 and a plurality of elements for reading, such as the charge detector 120, the charge transmitter 130, and the reset unit 140.

Assuming that the wavelength of visible light in the range of 400 to 700 nm, the wavelength range can be divided into three principal wavelength ranges: a blue wavelength range of 400 to 500 nm, which is a short wavelength range; a green wavelength range of 500 to 600 nm, which is a medium wavelength range; and a red wavelength range of 600 to 700 nm, which is a long wavelength range. In general, the thickness of the semiconductor substrate 102 having the photoelectric converter 110 formed therein is in the range of 4 to 5 μm. When light is incident on the rear surface of the semiconductor substrate 102, the photoelectric converter 110 receives light components in both the blue and green wavelength ranges. Meanwhile, all light components in the red wavelength range, that is, light components in the long wavelength range of 600 to 700 nm are not received by the photoelectric converter 110 and some of the light components may pass through the photoelectric converter 110 and the semiconductor substrate 102, resulting in the loss of light.

However, according to various exemplary embodiments of this invention, the reflecting film 190, having a plurality of refractive films 190a for refracting/reflecting light, is formed on the photoelectric converter 110, so that it can refract and reflect “passed” light towards the photoelectric converter 110. Therefore, as the reflecting film's reflectance is increased, a greater portion of light can be found to be incident on the photoelectric converter 110.

The reflecting film 190 having a high reflectance can be formed by including a plurality of refractive films 190a, each having a laminated structure of a first refractive film 191a and a second refractive film 192a.

In an exemplary embodiment, the first refractive film 191a may have a higher refractive index than the second refractive film 192a. For example, the first refractive film 191a may have a refractive index of 4, and the second refractive film 192a may have a refractive index of 1.4. The first refractive film 191a, having the refractive index of 4 may be, for example, a silicon film, and the second refractive film 192a, having the refractive index of 1.4, may be, for example, a silicon oxide film. In the refractive film 190a, the second refractive film 192a may be thicker than the first refractive film 191a. For example, the first refractive film 191a may be formed with a thickness of 400 nm, and the second refractive film 192a may be formed with a thickness of 800 nm. However, the invention is not limited thereto as any structure having a high reflectance can be formed using a combination of a sufficiently large refractive index with a sufficiently small refractive index film. The refractive films 109a, each having the refractive films 191a and 192a, cause light to be reflected at the respective interface, making it possible to further improve the overall reflectance.

A reflectance R by two refractive films having different refractive indexes can be represented by the following equation:

$$R = \frac{{( n 1 - n 2 )}^{2}}{{( n 1 + n 2 )}^{2}} , \qquad ( Equation 1 )$$

where R is the reflectance, n1 and n2 are indices of refraction, respectively.

For example, when the first refractive film 191a has a refractive index of n1 (e.g., 4) and the second refractive film 192a has a refractive index of n2 (e.g., 1.4), in the case of the reflecting film 190 having only one refractive film 109a, the reflectance R of 23% can be obtained by the above-mentioned Eq. 1. As a result, it is difficult to obtain the optimum reflectance. However, to increase the overall reflectance, the reflecting film 190 can have a laminated structure of refractive films 190a, which makes it possible to further improve the reflectance.

In various exemplary embodiments a plurality of refractive films 190a may be used. For example, in one exemplary embodiment, at least four refractive films 190a are provided in a laminated structure resulting in an improved reflectance.

Accordingly, some light components in the red wavelength range that have not been received by the photoelectric converter 110 can be refracted and reflected by the reflecting film 190 and received by the photoelectric converter 110, which makes it possible to improve photosensitivity.

In various exemplary embodiments, the interlayer insulating film 200 may be formed on the reflecting film 190. The interlayer insulating film 200 may be, for example, formed of an oxide film, or a combination of an oxide film and a nitride film. The interlayer insulating film 200 may include a plurality of wiring layers, and a plurality of interlayer insulating films may be provided. For the purpose of explanation, FIG. 3 is illustrated with a single interlayer insulating film 200. Multiple interlayer insulating films 200 may be used as deemed necessary.

A planarizing film 300 is formed on the rear surface of the polished semiconductor substrate 102. A color filter 310 and a domical microlens 320 are formed on the planarizing film 300 at a position corresponding to the photoelectric converter 110. The microlens 320 formed on the rear surface of the semiconductor substrate 102 makes it possible to form a back-illuminated image sensor 1 in which light illuminated from the rear side of the semiconductor substrate 102 is incident on the photoelectric converter 110. The back-illuminated image sensor 30 can prevent a reduced aperture ratio with respect to the photoelectric converter 110 arising from the layout of multi-layer wiring lines.

Accordingly, the reflecting film 190 refracts and reflects light in the red wavelength range, which is a long wavelength range of visible light, to be re-directed to the photoelectric converter 110, which reduces the loss of light in the red wavelength range.

The reflecting film 190 may be composed of a refractive film 190a, having a laminated first refractive film 191a with a high refractive index and second refractive film 192a having a smaller refractive index, but as discussed above, any combination that provides an increased reflectance may be used.

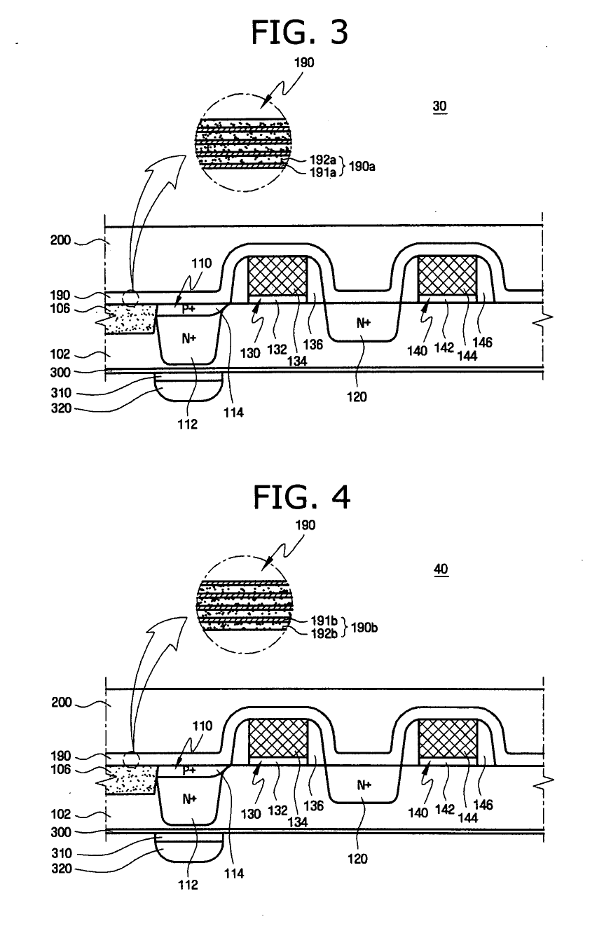

FIG. 4 shows an image sensor 40 having a refractive film 190b according to another exemplary embodiment of the invention. In this exemplary embodiment, detailed discussion of the same components as in the above-described embodiment is omitted.

In this exemplary embodiment, the refractive film 190b has a laminated structure composed of a first reflecting film 192b and a second refractive film 191b, wherein the first refractive film 192b has a smaller refractive index than the second refractive film 191b. The first refractive film 192b may be, for example, a silicon oxide film, and the second refractive film 191b may be, for example, a silicon film. The first refractive film 192b, however, may be thicker than the second refractive film 191b. For example, the first refractive film 192b may be formed with a thickness of 800 nm, and the second refractive film 191b may be formed with a thickness of 400 nm. Variations of the first versus second refractive films may be used as long as the refractive film having a small refractive index is thicker than the refractive film having the larger refractive index.

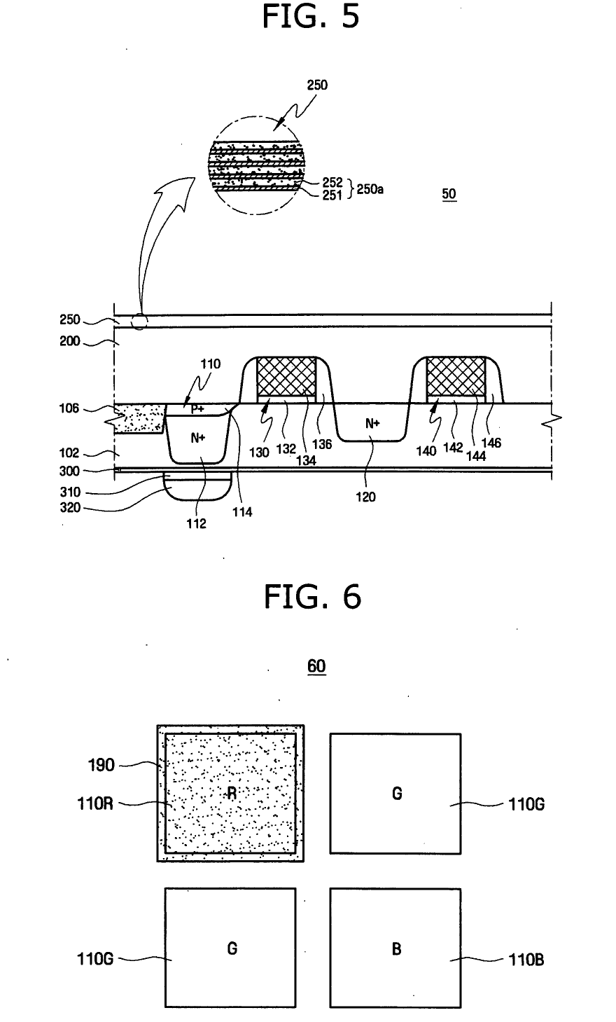

An image sensor 50 according to another exemplary embodiment of the invention will be described below with reference to FIG. 5. The image sensor 50, a reflecting film 250 is formed on an interlayer insulating film 200, unlike the exemplary embodiment shown in FIG. 3.

In this exemplary embodiment, the reflecting film 250 is formed on the interlayer insulating film 200. That is, the interlayer insulating film 200 is formed on a semiconductor substrate 102 having photoelectric converters 110 and a plurality of read gates formed thereon. Then, the reflecting film 250 is formed on the interlayer insulating film 200. In this exemplary embodiment, the reflecting film 250 is formed by laminating a plurality of refractive films 250a each having a first refractive film 251 and a second refractive film 252 formed thereon.

Although the reflecting film 250 is directly formed on the photoelectric converter 110, this exemplary embodiment enables light in the red wavelength range which has passed through the photoelectric converter 110 and the interlayer insulating film 200 to be refracted and reflected by the reflecting film 250 formed on the interlayer insulating film 200 and thus to be re-directed to the photoelectric converter 110.

FIG. 6 is a layout view of an image sensor 60 according to another exemplary embodiment of the invention. FIG. 6 shows photoelectric converters 110R, 110G, and 110B forming one unit pixel. The photoelectric converters 110R, 110G, and 110B store charges corresponding to light in the red, green, and blue wavelength ranges, respectively.

In this exemplary embodiment, a reflecting film 190 is selectively formed only on the red photoelectric converter 110R, for storing charge corresponding to light in the red wavelength range.

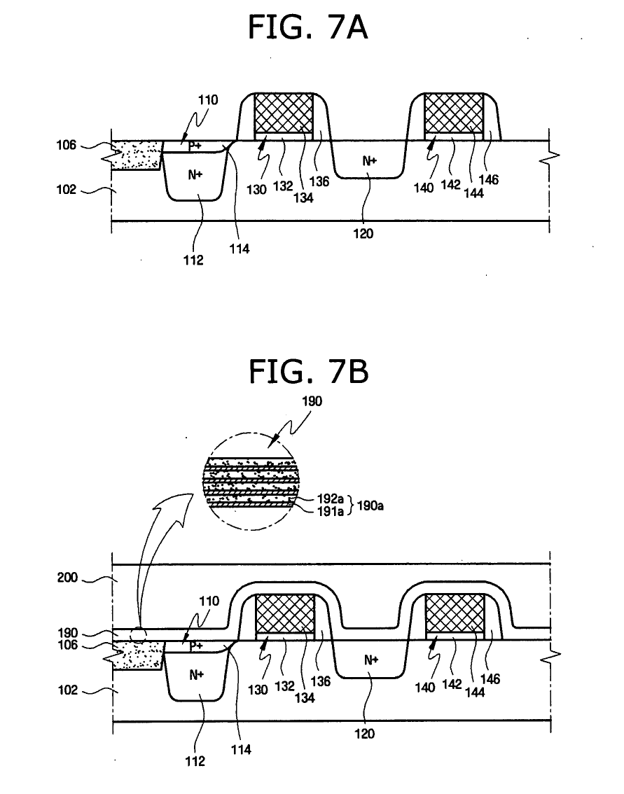

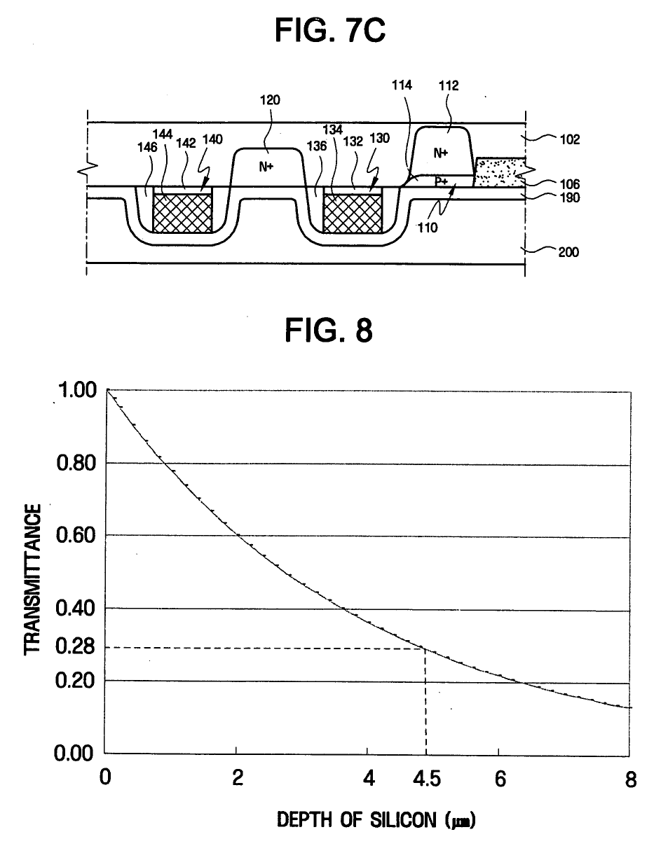

FIGS. 7A to 7C are diagrams illustrating an exemplary method of manufacturing the image sensors of this invention. Referring to FIG. 7A, the device isolation region 106 is formed in the semiconductor substrate 102, and the photoelectric converter 110, the charge detector 120, the charge transmitter 130, and the reset unit 140 are formed on the semiconductor substrate 102. The photoelectric converter 110, the charge detector 120, the charge transmitter 130, and the reset unit 140 may be formed, for example, on a P-type epitaxial layer and/or a well region by growing the P-type epitaxial layer on the semiconductor substrate 102 or by providing a separate well region thereon.

The photoelectric converter 110 includes the N+-type photodiode 112 and the P+-type pinning layer 114, wherein the photodiode 112 and the pinning layer 114 may be formed by two different ion implantation processes. For example, ions of an N+ dopant can be implanted into the semiconductor substrate 102 below the neighboring source and drain to form the photodiode 112. Then, ions of a P+ dopant can be implanted on the photodiode 112 with low energy and high dose to form the pinning layer 114. Of course, the concentration and implantation position of a dopant may vary according to the manufacturing process and the design. Therefore, other methods for generating the requisite photodiode may be used without departing from the spirit and scope of this invention.

The charge detector 120 may be formed by implanting ions of an N+ dopant. The charge transmitter 130 can be formed by forming the first gate electrode 134 on the first gate insulating film 132 and forming the first spacers 136 at both sides of the first gate electrode 134. The reset unit 140 can be formed in a similar manner.

Next, referring to FIG. 7B, the reflecting film 190 is formed on the semiconductor substrate 102 having the photoelectric converter 110, the charge detector 120, the charge transmitter 130, and the reset unit 140. The reflecting film 190 is formed by laminating a plurality of refractive films 190a each having the first refractive film 191a and the second refractive film 192a.

More specifically, the first refractive film 191a, having a lager refractive index than the second refractive film 192a, is conformally formed on the semiconductor substrate 102 which has the photoelectric converter 110, the charge detector 120, the charge transmitter 130, and the reset unit 140 formed thereon. Then, the second refractive film 192a is conformally formed on the first refractive film 191a. For example, the first refractive film 191a may be formed, for example, of a silicon film, and the second refractive film 192a may be formed, for example, of a silicon oxide film. However, the invention is not limited thereto as the first and second refractive films may be formed of, for example, silicon nitride films. The refractive film 190a may be formed any material as long as it can be formed in a laminated structure of thin films having different refractive indexes.

The second refractive film 192a is formed to have a thicker thickness than the first refractive film 191a. The thicknesses of the refractive films may be appropriately adjusted considering the relationship between the thickness and the refractive index. The first refractive film 191a may be formed by, for example, an LPCVD method using an SiH4 gas, and the thickness of the first refractive film 191a may depend on the processing conditions. As an example, the manufacturing process can be performed such that the first refractive film 191a has a refractive index of about 4 and a thickness of about 400 nm.

The second refractive film 192a may be formed with a thickness of about 800 nm by, for example, the LPCVD method or an ALD method. The refractive index of the second refractive film 192a may depend on the processing conditions. For example, a manufacturing process can be performed such that the second refractive film 192a has a refractive index of 1.4 to 1.6. The reflecting film 190 is then formed by laminating a plurality of refractive films 190a.

Referring to FIG. 7B, the interlayer insulating film 200 is formed on the reflecting film 190. The interlayer insulating film 200 may be formed, for example, of an oxide film or a nitride film. Then, a subsequent process of forming a metal insulating film on the interlayer insulating film 200 and forming metal wiring lines and contact via holes can be performed, the processes of which are well known in the art and, therefore, not discussed herein.

Next, referring to FIG. 7C, the rear surface of the semiconductor substrate 102 is polished. First, the semiconductor substrate 102 may be turned upside down, and the rear surface of the semiconductor substrate 102 is polished to a predetermined thickness. In general, the CMP process is used to polish the rear surface of the semiconductor substrate 102. In this way, a contaminant on the rear surface of the semiconductor substrate 102 is removed, and the thickness of silicon formed on the photoelectric converter 110 is reduced, which makes it possible to improve the sensitivity of the photoelectric converter 110 with respect to incident light.

Then, referring to FIG. 3, the microlens 320 is formed at a position corresponding to the photoelectric converter 110. First, a planarizing film 300 is formed on the polished rear surface of the semiconductor substrate 102.

The planarizing film 300 is formed to planarize the semiconductor substrate 102 before the color filter 310 is formed, and can prevent deformation of the color filter 310 due to the direct contact of the color filter 310 with the semiconductor substrate 102. In this exemplary embodiment, the planarizing film 300 may be achieved with an overcoating layer (OCL).

The color filter 310 may be formed by coating a color filter forming material and patterning the material using a suitable mask. A dyed photoresist may be used as the color filter forming material. The color filter 310 may be any one of red, green, and blue color filters.

The microlens 320 is formed on the color filter 310 at a position corresponding to the photoelectric converter 110. A photoresist having high light transmittance may be used as the microlens 320. More specifically, in an exemplary embodiment, a photoresist for a microlens is applied and patterned. Then, when a reflow process is performed using a heating process, it is possible to form a hemispheric microlens 320. Optionally, another overcoating layer (OCL) may be interposed between the color filter 310 and the microlens 320.

Accordingly, visible light can be refracted and reflected by the reflecting film 190 to be directed to the photoelectric converter 110. Specifically, light components in the red wavelength range that have “missed” the photoelectric converter 110 can be refracted and reflected by the reflecting film 190 so as to be incident on the photoelectric converter 110, resulting in an image sensor with improved photosensitivity.

The following experimental examples are provided as a demonstration of the improvements in reflectance achieved by various exemplary embodiments of the present invention. A rigorous description of the experimental results is omitted as one of ordinary skill in the art can understand the concepts being demonstrated without further elucidation.

FIG. 8 is a graph of an experimental example illustrating the relationship between the depth of a substrate and the transmittance of light in the long wavelength range of 650 nm, as viewed from an interlayer insulating film, formed on the upper side of the substrate, for a related art image sensor in which photoelectric converters are formed in the substrate, and microlenses are formed on the rear surface of the substrate at positions corresponding to the photoelectric converters. It is noted that FIG. 8's graph is for an image sensor that does not have a reflecting film having a laminated structure of a plurality of refractive films.

In the graph shown in FIG. 8, the X-axis indicates the depth of the substrate and the Y-axis indicates the transmittance in the image sensor. The graph of FIG. 8 shows that, when the general depth of the substrate with the photoelectric converters formed therein is 4.5 μm, the transmittance of light in the red wavelength range of 650 nm, which is a long wavelength range, is 28% for that given depth. The measured transmittance is obtained, as viewed from the interlayer insulating film on the upper side of the substrate, and the graph shows that 28% of light in the red wavelength range passes through the photoelectric converter in the substrate and the interlayer insulating film on the substrate. Therefore, when there is no reflecting film, a significant portion of the light components in the red wavelength range are found to be non-incident on the photoelectric converters, resulting in a loss of light.

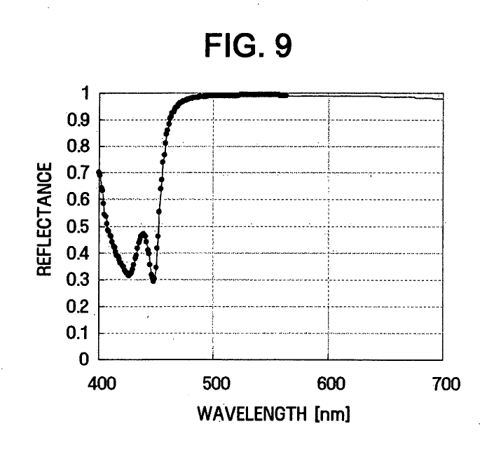

FIG. 9 is a graph of another experimental example illustrating the relationship between the reflectance of light and a wavelength range in an image sensor in which photoelectric converters are formed in a substrate, and a reflecting film having four refractive layers are laminated thereon, each having a first refractive film and a second refractive film.

In the refractive films, the first refractive film is formed of a silicon film having a refractive index of 4 and a thickness of about 400 nm, and the second refractive film is formed of a silicon oxide film having a refractive index of 1.4 and a thickness of about 800 nm.

In the graph shown in FIG. 9, the X-axis indicates the wavelength range of light, and the Y-axis indicates the reflectance of light by the reflecting film. As can be seen from this graph 9, the reflectance of light by the reflecting film is markedly higher, as the wavelength becomes longer.

Specifically, the reflectance of light by the reflecting film is approximately 100% for wavelengths greater than 450 nm, which means that the reflecting film reflects all the requisite light components. This means that all the “missed” light components passing through the photoelectric converter can be reflected by the reflecting film so as to be incident on the photoelectric converter.

Consequently, an image sensor with the reflecting film in accordance to various embodiments of this invention can refract and reflect light with a very high reflectance so that light components passing through the photoelectric converter can be directed to the photoelectric converter. Moreover, the reflecting film can refract and reflect light components in the red wavelength range as well as light components in the green and blue wavelength ranges so as to be incident on the photoelectric converter. Since the reflected light is incident on the photoelectric converter again, it is therefore possible to prevent the loss of light and to improve photosensitivity.

Exemplary embodiments of the invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the invention as set forth in the following claims.

What is claimed is:

1. An image sensor comprising:
a semiconductor substrate;
photoelectric converters formed in the substrate;
microlenses formed on a surface of the substrate at positions corresponding to the photoelectric converters; and
a reflecting film formed on an opposite surface of the substrate, the reflecting film having at lease one or more laminated refractive films, wherein each of the laminated refractive films has a first refractive film and a second refractive film.

2. The image sensor of claim 1, wherein the first refractive film has a larger refractive index than that of the second refractive film.

3. The image sensor of claim 2, wherein:
the first refractive film is a silicon film, and
the second refractive film is a silicon oxide film.

4. The image sensor of claim 2, wherein the second refractive film is thicker than the first refractive film.

5. The image sensor of claim 1, wherein the first refractive film has a smaller refractive index than that of the second refractive film.

6. The image sensor of claim 5, wherein:
the first refractive film is a silicon oxide film, and
the second refractive film is a silicon film.

7. The image sensor of claim 5, wherein the first refractive film is thicker than the second refractive film.

8. The image sensor of claim 1, further comprising:
a plurality of read gates formed between the photoelectric converters and the reflecting film on the substrate,
wherein the reflecting film is formed on the plurality of read gates and the substrate.

9. The image sensor of claim 1, further comprising:
an interlayer insulating film formed on the substrate having the photoelectric converters formed therein,
wherein the reflecting film is formed on the interlayer insulating film.

10. The image sensor of claim 1, wherein the reflecting film is formed on only a red photoelectric converter for storing a charge corresponding to a light component in a red wavelength range.

11. The image sensor of claim 1, wherein the reflecting film has a laminated structure of four or more refractive films.

12. The image sensor of claim 1, comprising:
color filters formed between the microlenses and the opposite surface of the substrate at the positions corresponding to the photoelectric converters.

13. A method of manufacturing an image sensor, the method comprising:
forming photoelectric converters in a semiconductor substrate;
forming a reflecting film on one surface of the substrate, the reflecting film having at least one or more laminated refractive films, each of the laminated refractive films having a first refractive film and a second refractive film;
polishing an opposite surface of the substrate; and
forming microlenses on the polished surface of the substrate at positions corresponding to the photoelectric converters.

14. The method of claim 13, wherein the first refractive film has a larger refractive index than that of the second refractive film.

15. The method of claim 14, wherein:
the first refractive film is a silicon film, and
the second refractive film is a silicon oxide film.

16. The method of claim 14, wherein the second refractive film is thicker than the first refractive film.

17. The method of claim 13, wherein the first refractive film has a smaller refractive index than that of the second refractive film.

18. The method of claim 17, wherein:
the first refractive film is a silicon oxide film, and
the second refractive film is a silicon film.

19. The method of claim 17, wherein the first refractive film is thicker than the second refractive film.

20. The method of claim 13, comprising:
forming a plurality of read gates between the photoelectric converters and the reflecting film on the substrate,
wherein the reflecting film is formed on the plurality of read gates and the substrate.

21. The method of claim 13, comprising:
forming an interlayer insulating film on the substrate having the photoelectric converters formed therein,
wherein the reflecting film is formed on the interlayer insulating film.

22. The method of claim 13, wherein the reflecting film is formed on only a red photoelectric converter for storing a charge corresponding to a light component in a red wavelength range.

23. The method of claim 13, wherein the reflecting film has a laminated structure of four or more refractive films.

24. The method of claim 13, comprising:
forming color filters between the microlenses and the opposite surface of the substrate at the positions corresponding to the photoelectric converters.
